(19) United States
(12) Patent Application Publication
(10) Pub. No.: US 2025/0341782 A1
(43) Pub. Date: Nov. 6, 2025

(54) CHROMATICALLY CORRECTED IMAGING ILLUMINATION OPTICAL UNIT FOR USE IN A LITHOGRAPHIC PROJECTION EXPOSURE APPARATUS

(71) Applicant: Carl Zeiss SMT GmbH, Oberkochen (DE)

(72) Inventors: Stig BIELING, Aalen (DE); Markus SCHWAB, Aalen (DE); Alexander EPPLE, Aalen (DE); Henning MEHNERT, Aalen (DE)

(21) Appl. No.: 19/272,388

(22) Filed: Jul. 17, 2025

Related U.S. Application Data
(63) Continuation of application No. PCT/EP2024/051205, filed on Jan. 19, 2024.

(30) Foreign Application Priority Data
Jan. 24, 2023 (DE) 10 2023 200 548.4

(51) Int. Cl. G03F 7/00; G02B 3/04

(52) U.S. Cl. CPC G03F 7/70241; G02B 3/04

(57) ABSTRACT

A chromatically corrected imaging illumination optical unit serves for use in a lithographic projection exposure apparatus, for example for imaging, in a manner adapted to a downstream projection optical unit, an illumination conditioning field via an imaging beam path into an object field of the downstream projection optical unit. The illumination optical unit has at least seven and at most twelve lens elements in the imaging beam path. The illumination optical unit has an overall transmission for illumination light of at least 85%. Such an illumination optical unit can be used to improve a throughput of a projection exposure apparatus equipped therewith and achieve a high illumination quality.

### CROSS-REFERENCE TO RELATED APPLICATIONS

The present application is a continuation of, and claims benefit under 35 USC 120 to, international application No. PCT/EP2024/051205, filed Jan. 19, 2024, which claims benefit under 35 USC 119 of German Application No. 10 2023 200 548.4, filed Jan. 24, 2023. The entire disclosure of each of these applications is incorporated by reference herein.

### FIELD

The disclosure relates to a chromatically corrected imaging illumination optical unit for use in a lithographic projection exposure apparatus. The disclosure also relates to an optical system in such an illumination optical unit, to an illumination system comprising such an illumination optical unit, to a projection exposure apparatus comprising such an illumination system, to a method for producing a structured component using such a projection exposure apparatus, and to a structured component produced using such a method.

### BACKGROUND

Chromatically corrected imaging illumination optical units for use in a lithographic projection exposure apparatus are known from DE 196 53 983 A1, U.S. Pat. No. 5,982,558, U.S. Pat. No. 7,551,361 B2, DE 101 13 612 A1 and WO 2009/095 052 A1.

DE 103 02 765 A1 discloses an optical arrangement comprising a lens element made of uniaxially refractive material. DE 10 2015 218 328 A1 discloses an optical system for field imaging and/or pupil imaging. DE 10 2008 015 775 A1 discloses a chromatically corrected lithography lens. DE 10 2017 207 582 A1 discloses a projection lens, a projection exposure apparatus and a projection exposure method.

### SUMMARY

The present disclosure seeks to develop an illumination optical unit of the type set forth at the outset in such a way that the throughput of a projection exposure apparatus equipped therewith is improved and a high illumination quality can be achieved.

According to an aspect, the disclosure provides a chromatically corrected imaging illumination optical unit for use in a lithographic projection exposure apparatus. The illumination optical unit can be used to image, in a manner adapted to a downstream projection optical unit, an illumination conditioning field via an imaging beam path into an object field of the downstream projection optical unit. The illumination optical unit has at least seven and at most twelve lens elements in the imaging beam path. The illumination optical unit has an overall transmission for illumination light of at least 85%.

According to the disclosure, it has been found that an illumination optical unit with a number of lens elements of between seven and twelve and an overall transmission of at least 85% can lead both to a high throughput and, owing to the number of optical lens-element faces of the illumination optical unit, to the possibility of good error correction. The overall transmission of the illumination optical unit for the illumination light may be at least 88%, may be at least 90% and may also be at least 91%. The illumination optical unit may be rotationally symmetric about an optical axis. The illumination conditioning field of the illumination optical unit can be preset via a REMA stop of the projection exposure apparatus. The conditioning field is then in an arrangement plane for the REMA stop. Certain details regarding the effect of such a REMA stop are explained in the aforementioned documents. The object field of the illumination optical unit may have a diameter corrected in respect of imaging aberrations which is greater than 10 mm. This diameter of the object field which is corrected in respect of imaging aberrations may be greater than 25 mm, may be greater than 50 mm, and may also be greater than 100 mm. The diameter of the object field which is corrected in respect of imaging aberrations may be in the region of 120 mm.

The illumination optical unit may comprise exactly seven lens elements. As an alternative, the illumination optical unit may also comprise exactly eight lens elements, exactly nine lens elements, exactly ten lens elements, exactly eleven lens elements or exactly twelve lens elements. In addition to the lens elements, the illumination optical unit may also comprise at least one plane-parallel optical component, for example a filter component.

At least three of the lens elements can be in the form of aspherical lens element. Such an aspherical form can allow for improved illumination quality. At least three, four or at least five of the lens elements may be in the form of aspherical lens elements. It is also possible for all the lens elements of the illumination optical unit to be in the form of aspherical lens elements. An aspherical lens element is a lens element with at least one aspherical face. It is also possible for both faces, that is the entry and the exit face, of an aspherical lens element to have an aspherical form.

The illumination optical unit can be designed for illumination light with a wavelength of 365 nm. Such a design can be suitable for a corresponding light source of the projection exposure apparatus, for example for the i-line of a mercury-vapour light source. The illumination optical unit may also be suitable for other UV or DUV wavelengths, for example for

248 nm or 193 nm.

A dioptric design of the illumination optical unit, that is without a curved mirror, can exhibit advantages in terms of production. Such a dioptric design of the illumination optical unit may be configured with or without at least one planar deflection mirror.

At most three different lens-element materials of the illumination optical unit can reduce the production outlay. The illumination optical unit may for example comprise at most two lens-element materials, this further reducing the production outlay. It has surprisingly been found that a reduction in the number of lens-element materials also can still allow sufficiently good chromatic correction.

One of the lens-element materials may be a flint glass. One of the lens-element materials may be a crown glass. One of the lens-element materials may be a quartz glass. If two different lens-element materials are used, this may involve the combination of flint glass and quartz glass, for example.

The illumination optical unit can comprise a doublet of lens elements, in which a concave lens element is fitted to a convex lens-element face of an adjacent lens element of the doublet such that, for at least one particular coordinate region of beam path coordinates along an optical axis of the illumination optical unit, it holds true that a plane, which is perpendicular to the optical axis in in this coordinate region, intersects both the concave lens element and the adjacent lens element of the doublet. Such a doublet can help enables good chromatic correction together with a compact structure. The sectional-plane coordinate region of the beam path coordinates along the optical axis of the illumination optical unit for which it holds true that a plane perpendicular to the optical axis within this coordinate region intersects both the concave lens element and the adjacent lens element of the doublet may have an extent which is greater than 5 mm and may also be greater than 10 mm, 15 mm or 20 mm. This sectional-plane coordinate region is generally smaller than 50 mm. The illumination optical unit may comprise multiple lens-element doublets, for example multiple doublets as discussed above.

This can apply for example to a triplet of lens elements, in which a concave lens element is adapted to a convex lens-element face of an adjacent lens element of the doublet, such that, for at least one particular coordinate region of beam path coordinates along an optical axis of the illumination optical unit, it holds true that a plane perpendicular to the optical axis in in this coordinate region intersects both the concave lens element and the adjacent lens element of the doublet. The above explanation in relation to the preceding paragraph applies to the extent of the at least one sectional-plane coordinate region. The illumination optical unit may comprise multiple lens-element triplets, such as multiple triplets as discussed above.

For two separate coordinate regions, separate from one another along the optical axis, of beam path coordinates along the optical axis of the illumination optical unit, it can hold true that a plane that is in these coordinate regions intersects both the biconcave lens element and one of the adjacent lens elements of the triplet. Such separate sectional-plane coordinate regions can result in the biconcave lens element being fitted to a corresponding convex lens-element face of the adjacent lens element on either side. This can result in a relatively compact structure with good chromatic correction. The above explanation can apply to the extent of the sectional-plane coordinate regions.

The illumination optical system can include a planar deflection mirror, wherein a constriction of a diameter of an overall beam compared to a maximum diameter of the overall beam in the imaging beam path upstream of the constriction of at least 25% is achieved in the imaging beam path upstream of the deflection mirror. Such a constriction of the overall beam can reduce size issues for the planar deflection mirror.

The illumination optical unit can have a magnifying effect between the illumination conditioning field and the object field of at least 2. Such a magnifying effect can enable good control of the illumination of an object field. An absolute magnification scale may be 4. The illumination optical unit may be designed without an intermediate image.

Features of related optical systems, illumination systems, projection exposure apparatus, production methods and structured components can correspond to those which have already been explained above with reference to the illumination optical unit. The light source of such an illumination system may be a mercury-vapour lamp, an excimer laser or an LED light source.

A structured component, such a microchip, for example a memory chip, can be produced.

### BRIEF DESCRIPTION OF THE DRAWINGS

Exemplary embodiments of the disclosure are explained in greater detail below with reference to the drawing, in which:

FIG. 1 schematically shows a meridional section through optical main groups of a microlithographic projection exposure apparatus;

FIG. 2 shows a meridional section through a chromatically corrected imaging illumination optical unit for use in the projection exposure apparatus; and

FIGS. 3 to 6 each show illustrations similar to FIG. 2 of further embodiments of a chromatically corrected imaging illumination optical unit for use in the projection exposure apparatus.

### DETAILED DESCRIPTION

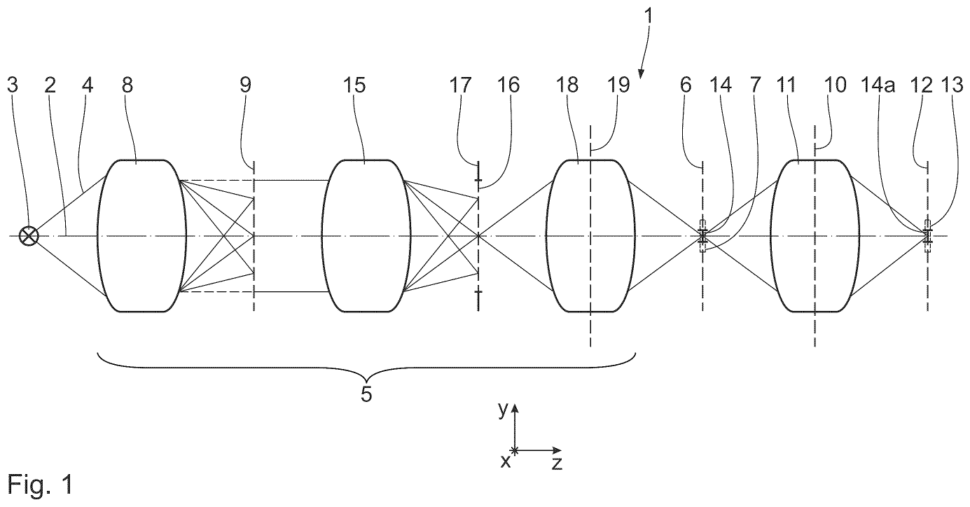

A projection exposure apparatus 1 is illustrated schematically in meridional section in FIG. 1 as regards its optical main groups. This schematic illustration shows the optical main groups as refractive optical elements. The optical main groups may just as well also be in the form of diffractive or reflective components or combinations or sub-combinations of refractive/diffractive/reflective assemblies of optical elements.

In order to facilitate the illustration of positional relationships, an xyz coordinate system will be used below. In FIG. 1, the x axis extends into the plane of the drawing perpendicularly in relation thereto. The y axis extends upwards in FIG. 1. In FIG. 1, the y axis extends to the right and parallel to an optical axis 2 of the projection exposure apparatus 1. This optical axis 2 may optionally also be folded multiple times.

The projection exposure apparatus 1 has a radiation source 3, which generates used light in the form of an illumination or imaging beam 4. The used light 4 has a wavelength in the deep ultraviolet (DUV) range, for example in the range between 100 nm and 200 nm, or in the ultraviolet (UV) range between 200 nm and 400 nm. As an alternative, the used light 4 may also have a wavelength in the extreme ultraviolet (EUV) range, for example between 5 nm and 30 nm. Exemplary wavelengths of the beam source 3 are 365 nm, 248 nm or 193 nm. Depending on the radiation source 3 used, a used wavelength spectrum utilized is narrowband, but can also have a greater broadband capacity, for example if an Hg discharge lamp is utilized.

An illumination optical unit 5 of the projection exposure apparatus 1 guides the used light 4 from the radiation source 3 to an object plane 6 of the projection exposure apparatus 1. An object, which is in the form of a reticle 7 and is to be imaged by the projection exposure apparatus 1, is arranged in the object plane 6. The reticle 7 is illustrated in dashed line in FIG. 1. The reticle 7 is carried by a holder, which is not illustrated, which enables a controlled scan displacement or step-by-step displacement.

As first optical main group, the illumination optical unit 5 firstly comprises a pupil shaping optical unit 8. This serves to generate a defined intensity distribution of the used light 4 in a downstream pupil plane 9. The pupil shaping optical unit 8 moreover serves as setting device for presetting various illumination settings. Corresponding setting devices that have, for example, adjustable optical components or interchangeable stops are known to those skilled in the art. The pupil shaping optical unit 8 forms the radiation source 3 in a plurality of secondary light sources in the pupil plane 9. The pupil shaping optical unit 8 may additionally also have a field-shaping function. Facet elements, honeycomb elements and/or diffractive optical elements can be used in the pupil shaping optical unit 8. The pupil plane 9 is optically conjugate to a further pupil plane 10 of a projection lens 11 of the projection exposure apparatus 1. The projection lens 11 is arranged downstream of the illumination optical unit 5 between the object plane 6 and an image plane 12. A wafer 13 is arranged in the image plane 12 and illustrated in dashed line in FIG. 1. The wafer 13 is carried by a holder, which is not illustrated, which enables a controlled scan displacement or step-by-step displacement. An object field 14 in the object plane 6 is imaged into an image field 14a in the image plane 12 by the projection lens 11.

A field lens-element group 15 as further optical main group of the illumination optical unit 5 is downstream of the pupil plane 9 arranged behind the pupil shaping optical unit 8. An intermediate image plane 16, which is conjugate to the object plane 6, is arranged behind the field lens-element group 15. The field lens-element group 15 is therefore a condenser group. A stop 17 for presetting a peripheral boundary of the object field 14 is in the intermediate image plane 16. The stop 17 is also referred to as REMA stop (reticle masking system for stopping down the reticle 7).

The intermediate image plane 16 is imaged into the object plane 6 by a lens group 18, which is also referred to as REMA lens-element group or REMA lens. The lens group 18 constitutes a further optical main group of the illumination optical unit 5. The lens group 18 is a chromatically corrected imaging illumination optical unit.

A further pupil plane 19 is between the field planes 16 and 6.

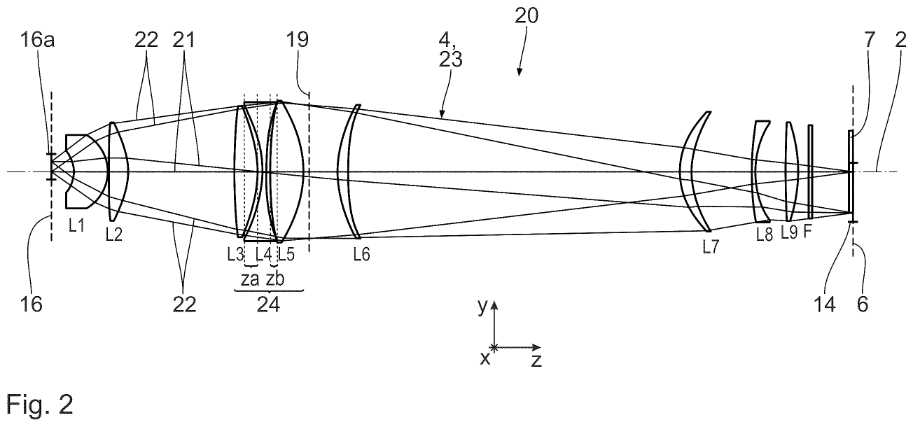

FIG. 2 shows a meridional section through an embodiment of an imaging illumination optical unit 20, which can be used instead of the lens group 18 as REMA lens in the projection exposure apparatus 1.

The illumination optical unit 20 serves to image, in a manner adapted to the downstream projection optical unit 11, an illumination conditioning field 16a in the intermediate image plane 16, preset by the stop 7, into the object field 14 of the downstream projection optical unit 11.

FIG. 2 illustrates the course of a respective main beam 21 and peripheral, pupil-delimiting beams 22, which start from two mutually spaced field points. This depicts an imaging beam path of the illumination light 4.

The illumination optical unit 20 has a total of nine lens elements L1 to L9, which are numbered in the order in which they are impinged upon in the imaging beam path 23, in the imaging beam path 23 between the illumination conditioning field 16a and the object field 14.

The lens elements L1 and L2 form a condenser lens-element group of the illumination optical unit 20 in the vicinity of the conditioning field 16a. The lens elements of this condenser lens-element group of the illumination optical unit 20 are made of the same lens-element material.

The lens elements L3 to L6 form a lens-element group, close to the pupil, of the illumination optical unit 20 in the vicinity of the pupil plane 19.

The lens elements L7 to L9 form a field lens-element group of the illumination optical unit 20 in the vicinity of the object field 14.

In front of the object field 14, a graduated filter F of the illumination optical unit 20 is downstream of the lens element L9. The graduated filter F is a static neutral density filter with an absorbent layer. The graduated filter F ensures homogeneity of the intensity of an illumination of the object field 14 or the image field 14a.

The illumination optical unit 20 has an overall transmission for the illumination light 4 of at least 90.0%.

The illumination optical unit 20 is designed for illumination light 4 with a wavelength of 365 nm.

The illumination optical unit 20 has a dioptric design, that is does not have a mirror with a beam-influencing effect. In the embodiment illustrated, the illumination optical unit 20 actually also does not have a planar deflection mirror. There is space for such a planar deflection mirror between the lenses L6 and L7, with the result that, in a further embodiment of the illumination optical unit comprising such a planar deflection mirror, the imaging beam path 23 may be folded.

The lens elements L3 to L5 form a triplet 24. The lens element L4 of the triplet that is in between them has a biconcave design and is fitted between two convex lens-element faces of the respective adjacent lens elements L3 and L5 of the triplet. This matching is such that, for coordinate regions za, zb of beam path coordinates along the optical axis 2 of the illumination optical unit 20, it holds true that a plane (the respective xy planes at the region boundaries za, zb are illustrated in dashed line in FIG. 2) which is perpendicular to the optical axis 2 in the respective coordinate region za, zb intersects both the biconcave lens element L4 and one of the adjacent lens elements L3, L5 of the triplet 24. The two coordinate regions za, in which the lens elements L4 and L3 are intersected, and zb, in which the lens elements L4 and L5 and intersected, are separate from one another along the optical axis 2, and are thus spaced from one another along the optical axis 2. The coordinate regions za, zb have an extent along the optical axis 2 in the range between 1 mm and 50 mm, for example in the range between 5 mm and 25 mm. The extent of the coordinate region za is in the region of 20 mm. The extent of the coordinate region zb is in the region of 5 mm.

The illumination optical unit 20 provides magnification by a factor of 4 between the conditioning field 16a and the object field 14.

The object field 14 has a diameter which is corrected in terms of imaging aberrations of approximately 120 mm. This diameter, corrected in terms of imaging aberrations, of the object field 14 is greater than 10 mm, greater than 25 mm, greater than 50 mm and greater than 100 mm.

A spacing between the intermediate image plane 16 and the object plane 6 is 1200 mm.

The lens elements L1, L2, L3, L5, L6, L7 and L8 are made of a crown glass (FK5) with a refractive index in the region of 1.50 at the illumination light wavelength. The lens elements L4 and L9 are made of a flint glass (LLF1) with a refractive index in the region of 1.58 at the illumination light wavelength. The lens elements L1 to L9 of the illumination optical unit 20 are made of exactly two different lens-element materials, specifically on the one hand the crown glass and on the other hand the flint glass.

The following tables show design data for the illumination optical unit 20 according to FIG. 2.

In the first column, the first table for FIG. 2 shows optical faces of the illumination optical unit, which are numbered from left to right.

“Faces 1 and 2” constitute the intermediate image plane 16.

“Faces 3 and 4” describe the entry and exit faces of the lens element L1.

“Faces 5 and 6” describe the entry and exit faces of the lens element L2. The exit surface of the lens element L2 is in the form of an asphere, the asphere coefficients of which are tabulated according to the following asphere formula:

$$p ( h ) = [ ( ( 1 / r ) {h}^{2} ) / ( 1 + SQRT ( 1 - ( 1 + K ) {( 1 / r )}^{2} {h}^{2} ) ) ] + C 1 \cdot {h}^{4} + C 2 \cdot {h}^{6} + …$$

### in Table 2 for FIG. 2.

“Faces 7 and 8” describe the entry and exit faces of the lens element L3.

“Faces 9 and 10” describe the entry and exit faces of the lens element L4.

“Faces 11 and 12” describe the entry and exit faces of the lens element L5. The entry face of the lens element L5 in turn is in the form of an asphere, the asphere coefficients of which are tabulated in Table 3 for FIG. 2.

“Face 13” describes an arrangement plane for a pupil stop, that is the position of the pupil plane 19. In the illumination optical unit 20, the pupil plane 19 is between the lens elements L5 and L6.

“Faces 14 and 15” describe the entry and exit faces of the lens element L6. The exit face of the lens element L6 in turn is in the form of an asphere, the asphere coefficients of which are tabulated in Table 4 for FIG. 2.

“Face 16” describes a possible arrangement position of a planar deflection mirror, which is not illustrated in FIG. 2.

“Faces 17 and 18” describe an entry and an exit face of the lens element L7. The entry face of the lens element L7 in turn is in the form of an asphere, the asphere coefficients of which are tabulated in Table 5 for FIG. 2.

“Faces 19 and 20” describe the entry and exit faces of the lens element L8.

“Faces 21 and 22” describe the entry and exit faces of the lens element L9. The exit face of the lens element L9 in turn is in the form of an asphere, the asphere coefficients of which are tabulated in Table 6 for FIG. 2.

“Faces 23 and 24” describe the entry and exit faces of the graduated filter F, which is likewise made of crown glass.

“Faces 25 and 26” describe an entry and an exit face of the reticle 7 with a substrate of quartz glass (Suprasil).

The lens elements L1 to L9 are rotationally symmetrical about the optical axis 2. A total of five of the nine lens elements are in the form of aspherical lens elements. In each of these five aspherical lens elements, in each case only exactly one of the two optical faces is in the form of an asphere, wherein the other one of the two optical faces of the respective lens element is in the form of a spherical face.

The illumination optical unit 20 does not have an intermediate image plane.

Table 1 for FIG. 2

| | | | | | REFRACTIVE | |
|---|---|---|---|---|---|---|
| | | | | | INDEX | |
| FACE | RADII | | THICKNESS | GLASSES | 365.5 nm | SEMIDIAMETER |
| 1 | 0.000000 | | 0.0000 | | 1.000000 | 15.201 |
| 2 | 0.000000 | | 33.4083 | | 1.000000 | 15.201 |
| 3 | −47.154742 | | 51.0868 | FK5 | 1.503934 | 31.332 |
| 4 | −62.097291 | | 0.7001 | | 1.000000 | 54.983 |
| 5 | 876.892861 | | 29.6831 | FK5 | 1.503934 | 72.111 |
| 6 | −112.260533 | Asphere | 158.6215 | | 1.000000 | 73.358 |
| 7 | 809.022117 | | 36.2291 | FK5 | 1.503934 | 98.562 |
| 8 | −205.492719 | | 6.6463 | | 1.000000 | 98.796 |
| 9 | −175.852713 | | 4.0076 | LLF1 | 1.579164 | 98.387 |
| 10 | 324.841427 | | 7.5996 | | 1.000000 | 104.559 |
| 11 | −2308.992575 | Asphere | 49.2279 | FK5 | 1.503934 | 104.853 |
| 12 | −179.202113 | | 7.0159 | | 1.000000 | 105.547 |
| 13 | 0.000000 | Stop | 44.3644 | | 1.000000 | 100.762 |
| 14 | 190.277871 | | 16.1436 | FK5 | 1.503934 | 100.191 |
| 15 | 628.632679 | Asphere | 305.2560 | | 1.000000 | 99.241 |
| 16 | 0.000000 | Deflection | 192.6634 | | 1.000000 | 129.593 |
| | | mirror | | | | |
| 17 | 117.275396 | Asphere | 16.5329 | FK5 | 1.503934 | 88.809 |
| 18 | 148.250792 | | 91.1074 | | 1.000000 | 87.182 |
| 19 | 479.413957 | | 5.0241 | FK5 | 1.503934 | 75.558 |
| 20 | 133.042920 | | 45.5140 | | 1.000000 | 72.187 |
| 21 | 1864.406648 | | 18.8771 | LLF1 | 1.579164 | 73.922 |
| 22 | −209.649304 | Asphere | 16.2712 | | 1.000000 | 74.063 |
| 23 | 0.000000 | | 4.0000 | FK5 | 1.503934 | 69.906 |
| 24 | 0.000000 | | 55.7500 | | 1.000000 | 69.523 |
| 25 | 0.000000 | | 6.2500 | SUPRASIL | 1.474471 | 61.504 |
| 26 | 0.000000 | | 0.0000 | | 1.000000 | 61.069 |

Table 2 for FIG. 2
FACE 6

| | |
|---|---|
| K | 0.0000000000 |
| C1 | 1.3978383887e−07 |
| C2 | 8.4361042350e−12 |
| C3 | −4.1031031362e−16 |
| C4 | 7.1049614540e−20 |
| C5 | 5.0420939318e−24 |
| C6 | −4.7838361500e−28 |

Table 3 for FIG. 2
FACE 11

| | |
|---|---|
| K | 0.0000000000 |
| C1 | 1.7029932647e−07 |
| C2 | −7.3936840682e−12 |
| C3 | 1.3245249758e−16 |
| C4 | 1.2442350080e−22 |

Table 4 for FIG. 2
FACE 15

| | |
|---|---|
| K | 0.0000000000 |
| C1 | 9.8483547350e−08 |
| C2 | −1.5043660294e−12 |
| C3 | 1.6440078913e−16 |
| C4 | −2.7643515570e−21 |

Table 5 for FIG. 2
FACE 17

| | |
|---|---|
| K | 0.0000000000 |
| C1 | 4.9297281500e−09 |
| C2 | −1.6147772848e−12 |
| C3 | 1.3012799782e−16 |
| C4 | −1.9716901478e−20 |

Table 6 for FIG. 2
FACE 22

| | |
|---|---|
| K | 0.0000000000 |
| C1 | 3.7448322936e−08 |
| C2 | −7.5270730209e−13 |
| C3 | 2.2674144098e−16 |
| C4 | −2.2453178888e−20 |

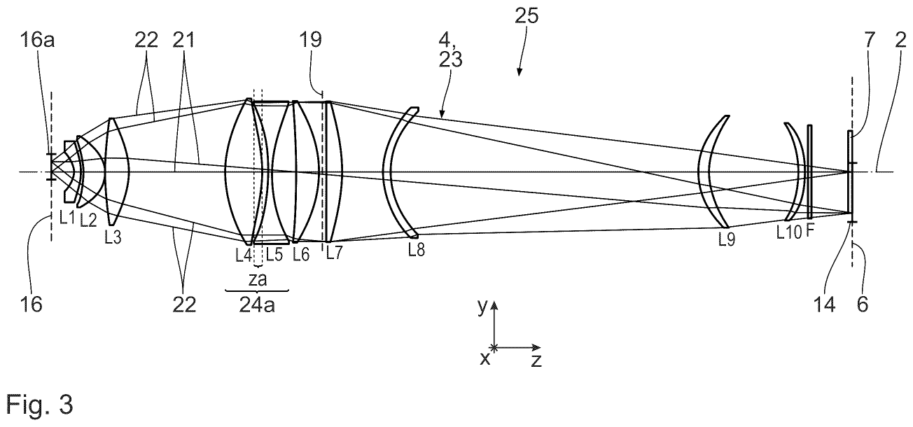

With reference to FIG. 3, a description is given below of a further embodiment of an illumination optical unit 25, which can be used instead of the illumination optical unit 20 as REMA lens in the projection exposure apparatus 1. Components and functions that correspond to those which were already explained above with reference to FIGS. 1 and 2 and for example with reference to FIG. 2 have the same reference signs and are not discussed in detail again.

The illumination optical unit 25 has a total of ten lens elements L1 to L10. The graduated filter F in turn is arranged between the last lens element L10 in the imaging beam path 23 and the reticle 7.

The illumination optical unit 25 has an overall transmission of 90.0%.

The lens elements L1, L5 and L10 are made of flint glass (LLF1) and the other lens elements L2 to L4 and L6 to L9 are made of crown glass (FK5).

The lens elements L1 to L3 form a condenser lens-element group of the illumination optical unit 25 in the vicinity of the conditioning field 16a.

The lens elements L4 to L8 form a lens-element group, close to the pupil, of the illumination optical unit 25 in the vicinity of the pupil plane 19.

The lens elements L9 and L10 form a field lens-element group in the vicinity of the object field 14.

The lens elements L4 and L5 form a doublet 24a of lens elements. The concave lens element L5 is fitted to an adjacent, convex lens-element face of the lens element L4 of the doublet such that, for a coordinate region za, it holds true in turn that, along the optical axis 2 of the illumination optical unit 25, a plane which is perpendicular to the optical axis 2 in this coordinate region za intersects both the concave lens element L5 and the adjacent lens element L4 of the doublet.

In the illumination optical unit 25, there are also two different lens-element materials in the case of the condenser lens-element group L1 to L3.

The optical design data of the illumination optical unit 25 are provided by the following design tables, which correspond to the tables for FIG. 2 in terms of the structure.

The exit face of the lens element L1, the entry face of the lens element L6, the entry face of the lens element L9 and the exit face of the lens element L10 are in the form of aspheres, the asphere coefficients of which are tabulated in Tables 2 to 5 for FIG. 3.

In turn, there is space between the lens elements L8 and L9 for a planar deflection mirror, which is reported in Table 1 for FIG. 3 as “face 20” by way of example.

In Table 1 for FIG. 3, the pupil plane 19 in which a pupil stop may be arranged is reported as “face 15”. In the illumination optical unit 25, the pupil plane 19 is between the lens elements L6 and L7.

“Faces 27 and 28” in turn stand for the position of the entry and exit faces of the reticle 7.

Table 1 for FIG. 3

| | | | | | REFRACTIVE | |
|---|---|---|---|---|---|---|
| | | | | | INDEX | |
| FACE | RADII | | THICKNESS | GLASSES | 365.5 nm | SEMIDIAMETER |
| 1 | 0.000000 | | 0.0000 | | 1.000000 | 15.201 |
| 2 | 0.000000 | | 35.6883 | | 1.000000 | 15.201 |
| 3 | −41.097725 | | 8.8707 | LLF1 | 1.579164 | 31.204 |
| 4 | −118.007859 | Asphere | 4.9369 | | 1.000000 | 45.674 |
| 5 | −137.731947 | | 32.0440 | FK5 | 1.503934 | 49.995 |
| 6 | −55.786142 | | 0.7485 | | 1.000000 | 53.048 |
| 7 | 648.268979 | | 34.6741 | FK5 | 1.503934 | 79.912 |
| 8 | −142.005608 | | 145.2147 | | 1.000000 | 81.222 |
| 9 | 199.149325 | | 54.4084 | FK5 | 1.503934 | 109.266 |
| 10 | −357.016155 | | 11.2046 | | 1.000000 | 108.647 |
| 11 | −255.357547 | | 4.9967 | LLF1 | 1.579164 | 106.746 |
| 12 | 221.305131 | | 36.1303 | | 1.000000 | 104.215 |
| 13 | −1604.088294 | Asphere | 32.9565 | FK5 | 1.503934 | 105.609 |
| 14 | −186.905406 | | 5.9988 | | 1.000000 | 106.481 |
| 15 | 0.000000 | Stop | 6.5359 | | 1.000000 | 106.154 |
| 16 | −10466.860203 | | 23.3759 | FK5 | 1.503934 | 106.305 |
| 17 | −296.911961 | | 61.6428 | | 1.000000 | 106.414 |
| 18 | 139.443538 | | 10.9760 | FK5 | 1.503934 | 97.622 |
| 19 | 126.257130 | | 239.7948 | | 1.000000 | 93.397 |
| 20 | 0.000000 | Deflection | 223.0600 | | 1.000000 | 124.121 |
| | | mirror | | | | |
| 21 | 115.871602 | Asphere | 14.0477 | FK5 | 1.503934 | 84.379 |
| 22 | 123.701378 | | 135.4840 | | 1.000000 | 81.678 |
| 23 | −128.784421 | | 12.4614 | LLF1 | 1.579164 | 72.400 |
| 24 | −99.845257 | Asphere | 1.0600 | | 1.000000 | 73.740 |
| 25 | 0.000000 | | 4.0000 | FK5 | 1.503934 | 69.751 |
| 26 | 0.000000 | | 55.7500 | | 1.000000 | 69.375 |
| 27 | 0.000000 | | 6.2500 | SUPRASIL | 1.474471 | 61.465 |
| 28 | 0.000000 | | 0.0000 | | 1.000000 | 61.050 |

Table 2 for FIG. 3
FACE 4

| | |
|---|---|
| K | 0.0000000000 |
| C1 | 7.6247709121e−07 |
| C2 | −1.2104026966e−10 |
| C3 | 9.2330200600e−16 |
| C4 | 2.2219538098e−18 |

Table 3 for FIG. 3
FACE 13

| | |
|---|---|
| K | 0.0000000000 |
| C1 | −1.7508188699e−08 |
| C2 | 1.0257377630e−12 |
| C3 | −7.8552731406e−17 |
| C4 | 4.4209555397e−21 |

Table 4 for FIG. 3
FACE 21

| | |
|---|---|
| K | 0.0000000000 |
| C1 | −3.6248868257e−09 |
| C2 | 3.2786024086e−12 |
| C3 | −4.7412545643e−16 |
| C4 | 4.0596735709e−20 |

Table 5 for FIG. 3
FACE 24

| | |
|---|---|
| K | 0.0000000000 |
| C1 | 1.5385855888e−07 |
| C2 | −1.6159747582e−12 |
| C3 | 1.0316186680e−15 |
| C4 | 7.0634719992e−20 |

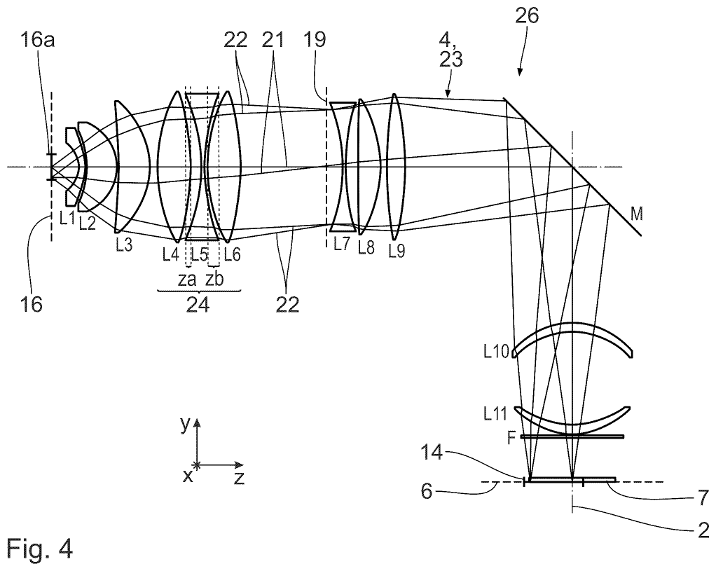

With reference to FIG. 4, a description is given below of a further embodiment of an illumination optical unit 26, which can be used instead of the illumination optical unit 20 as REMA lens in the projection exposure apparatus 1. Components and functions that correspond to those which were already explained above with reference to FIGS. 1 to 3 and for example with reference to FIGS. 2 and 3 have the same reference signs and are not discussed in detail again.

The illumination optical unit 26 has a total of eleven lens elements L1 to L11. A planar deflection mirror M, which deflects a main beam 212 of a central field point by 90°, is arranged between the lens elements L9 and L10.

The lens elements L1 to L3 form a condenser lens-element group of the illumination optical unit 26. The lens elements L7 to L9 form a lens-element group, close to the pupil, of the illumination optical unit 26. The pupil plane 19 lies directly in front of the lens element L7 in the imaging beam path.

Between these lens-element groups is the lens-element group comprising the lens elements L4 to L6, which in turn form a lens-element triplet comprising a biconcave lens element L5, which is fitted between the two convex lens elements L4 and L6 such that in turn sectional coordinate regions za, zb are produced in accordance with what was explained above in connection with FIG. 2.

The lens elements L1, L5, L7, L10 and L11 are made of flint glass (LLF1). The lens elements L2 to L4, L6, L8 and L9 are made of crown glass (FK5).

The illumination optical unit 26 has an overall transmission of 88.5%.

The following tables show design data for the illumination optical unit 26 according to FIG. 4.

The exit face of the lens element L1, the entry face of the lens element L7 and the exit face of the lens element L11 are in the form of asphere faces, the coefficients of which are tabulated in Tables 2 to 4 for FIG. 4.

In Table 1 for FIG. 4, “face 15” depicts the pupil plane 19.

“Face 22” depicts the arrangement plane for the mirror M.

“Faces 29 and 30” depict the entry and exit faces of the reticle 7.

Table 1 for FIG. 4

| | | | | | REFRACTIVE | |
|---|---|---|---|---|---|---|
| | | | | | INDEX | |
| FACE | RADII | | THICKNESS | GLASSES | 365.5 nm | SEMIDIAMETER |
| 1 | 0.000000 | | 0.0000 | | 1.000000 | 15.201 |
| 2 | 0.000000 | | 39.6612 | | 1.000000 | 15.201 |
| 3 | −43.071133 | | 9.1371 | LLF1 | 1.579164 | 33.297 |
| 4 | −88.951126 | Asphere | 2.3185 | | 1.000000 | 46.363 |
| 5 | −116.219867 | | 42.7434 | FK5 | 1.503934 | 49.117 |
| 6 | −70.238530 | | 2.1371 | | 1.000000 | 63.172 |
| 7 | −854.234003 | | 45.6153 | FK5 | 1.503934 | 88.609 |
| 8 | −118.542375 | | 11.2220 | | 1.000000 | 91.702 |
| 9 | 234.258950 | | 47.4958 | FK5 | 1.503934 | 104.225 |
| 10 | −349.966089 | | 15.5215 | | 1.000000 | 103.745 |
| 11 | −240.812724 | | 3.9999 | LLF1 | 1.579164 | 101.288 |
| 12 | 277.473259 | | 4.9354 | | 1.000000 | 101.872 |
| 13 | 236.200610 | | 46.7367 | FK5 | 1.503934 | 104.595 |
| 14 | −369.931026 | | 125.7620 | | 1.000000 | 104.579 |
| 15 | 0.000000 | Stop | 21.6899 | | 1.000000 | 82.459 |
| 16 | −263.068566 | Asphere | 3.9999 | LLF1 | 1.579164 | 82.680 |
| 17 | 332.085484 | | 18.1816 | | 1.000000 | 87.709 |
| 18 | 5724.848529 | | 31.9457 | FK5 | 1.503934 | 91.195 |
| 19 | −187.253944 | | 9.9824 | | 1.000000 | 93.120 |
| 20 | 701.592695 | | 25.6467 | FK5 | 1.503934 | 100.393 |
| 21 | −403.436133 | | 241.2678 | | 1.000000 | 100.753 |
| 22 | 0.000000 | Deflection | 223.9282 | | 1.000000 | 134.956 |
| | | mirror | | | | |
| 23 | 111.542494 | | 13.1686 | LLF1 | 1.579164 | 83.449 |
| 24 | 113.935870 | | 133.3578 | | 1.000000 | 80.138 |
| 25 | −126.352882 | | 13.8645 | LLF1 | 1.579164 | 72.773 |
| 26 | −99.448893 | Asphere | 1.6808 | | 1.000000 | 74.418 |
| 27 | 0.000000 | | 4.0000 | FK5 | 1.503934 | 70.059 |
| 28 | 0.000000 | | 55.7500 | | 1.000000 | 69.675 |
| 29 | 0.000000 | | 6.2500 | SUPRASIL | 1.474471 | 61.570 |
| 30 | 0.000000 | | 0.0000 | | 1.000000 | 61.009 |

Table 2 for FIG. 4
FACE 4

| | |
|---|---|
| K | 0.0000000000 |
| C1 | 5.1566837293e−07 |
| C2 | 2.3571855613e−11 |
| C3 | 2.8478120846e−15 |
| C4 | −1.7657237108e−18 |

Table 3 for FIG. 4
FACE 16

| | |
|---|---|
| K | 0.0000000000 |
| C1 | −1.9858154496e−08 |
| C2 | −3.8868489920e−13 |
| C3 | 1.3698417265e−17 |
| C4 | −4.0008110314e−21 |

Table 4 for FIG. 4
FACE 26

| | |
|---|---|
| K | 0.0000000000 |
| C1 | 1.3082537358e−07 |
| C2 | 2.7157620429e−12 |
| C3 | 1.9063364805e−16 |
| C4 | 9.2120975249e−20 |
| C5 | 1.4353799155e−24 |

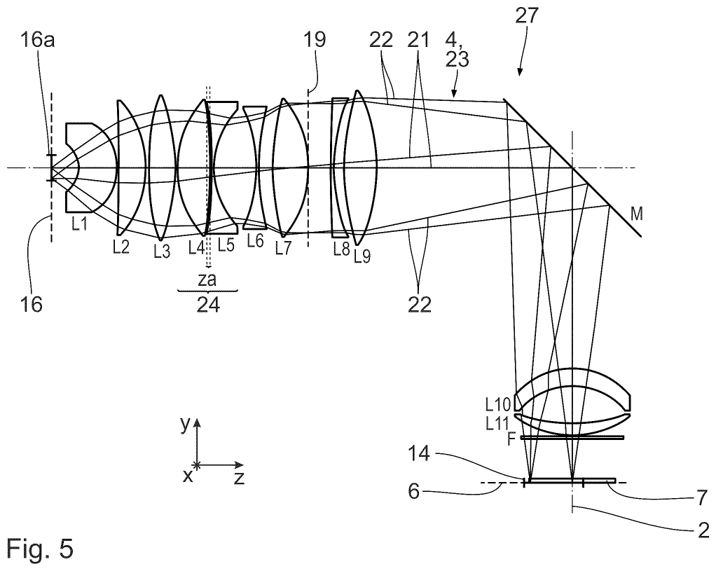

With reference to FIG. 5, a description is given below of a further embodiment of an illumination optical unit 27, which can be used instead of the illumination optical unit 20 as REMA lens in the projection exposure apparatus 1. Components and functions that correspond to those which were already explained above with reference to FIGS. 1 to 4 and for example with reference to FIGS. 2 and 4 have the same reference signs and are not discussed in detail again.

The illumination optical unit 27 has a total of eleven lens elements L1 to L11.

The lens elements L1 to L3 form a condenser lens-element group. The lens elements L4 to L9 form a lens-element group close to the pupil. The lens elements L10 and L11 form a field lens-element group.

The lens element L1 is made of quartz glass (SILUV) with high UV transmission. The lens elements L2 to L4, L7, L9 and L11 are made of crown glass (FK5). The lens elements L5, L6, L8 and L10 are made of flint glass (LLF1).

Overall, the lens elements L1 to L11 of the illumination optical unit 27 are thus made of three different materials.

The 90°-deflection mirror M is arranged between the lens elements L9 and L10.

The illumination optical unit 27 has an overall transmission of 88.1%.

The following tables show design data for the illumination optical unit 27 according to FIG. 5.

The quartz glass material of the lens element L1 has a refractive index of approximately 1.47 at the illumination light wavelength.

The entry face of the lens element L2, the entry face of the lens element L9 and the exit face of the lens element L11 are in the form of asphere faces, the coefficients of which are shown in Tables 2 to 4 for FIG. 5.

In Table 1, “face 17” stands for the pupil plane 19.

In Table 1, “face 22” stands for the 90°-deflection mirror M.

“Faces 29 and 30” stand for the entry and exit faces of the reticle 7.

The lens elements L8 and L8 in turn form a doublet with a sectional plane coordinate region za in accordance with what was explained above in connection for example with FIG. 3.

Table 1 for FIG. 5

| | | | | | REFRACTIVE | |
|---|---|---|---|---|---|---|
| | | | | | INDEX | |
| FACE | RADII | | THICKNESS | GLASSES | 365.5 nm | SEMIDIAMETER |
| 1 | 0.000000 | | 0.0000 | | 1.000000 | 15.201 |
| 2 | 0.000000 | | 38.8180 | | 1.000000 | 15.201 |
| 3 | −46.375081 | | 56.3097 | SILUV | 1.474477 | 33.592 |
| 4 | −74.602835 | | 0.7000 | | 1.000000 | 63.383 |
| 5 | 1141.672413 | Asphere | 39.5814 | FK5 | 1.503934 | 84.639 |
| 6 | −145.202607 | | 4.1963 | | 1.000000 | 88.561 |
| 7 | 380.453883 | | 38.8368 | FK5 | 1.503934 | 99.938 |
| 8 | −282.847134 | | 2.2902 | | 1.000000 | 100.352 |
| 9 | 149.973132 | | 46.9288 | FK5 | 1.503934 | 94.633 |
| 10 | −733.141506 | | 1.8070 | | 1.000000 | 92.226 |
| 11 | −673.610864 | | 4.0328 | LLF1 | 1.579164 | 91.332 |
| 12 | 120.982433 | | 60.9935 | | 1.000000 | 79.640 |
| 13 | −193.923271 | | 4.0000 | LLF1 | 1.579164 | 79.770 |
| 14 | 364.831429 | | 19.5968 | | 1.000000 | 84.989 |
| 15 | 398.915248 | | 51.2054 | FK5 | 1.503934 | 94.535 |
| 16 | −161.054049 | | 1.7799 | | 1.000000 | 96.049 |
| 17 | 0.000000 | Stop | 30.7228 | | 1.000000 | 93.419 |
| 18 | 2169.967720 | | 4.0003 | LLF1 | 1.579164 | 96.107 |
| 19 | 248.107525 | | 14.6242 | | 1.000000 | 96.907 |
| 20 | 322.053027 | Asphere | 47.2360 | FK5 | 1.503934 | 100.007 |
| 21 | −248.013400 | | 282.3400 | | 1.000000 | 101.457 |
| 22 | 0.000000 | Deflection | 288.3692 | | 1.000000 | 133.805 |
| | | mirror | | | | |
| 23 | 109.991352 | | 25.4853 | LLF1 | 1.579164 | 80.943 |
| 24 | 98.944234 | | 53.1787 | | 1.000000 | 72.756 |
| 25 | −233.964190 | | 16.7496 | FK5 | 1.503934 | 72.429 |
| 26 | −127.917172 | Asphere | 2.2172 | | 1.000000 | 73.120 |
| 27 | 0.000000 | | 4.0000 | FK5 | 1.503934 | 69.863 |
| 28 | 0.000000 | | 55.7500 | | 1.000000 | 69.479 |
| 29 | 0.000000 | | 6.2500 | SUPRASIL | 1.474471 | 61.386 |
| 30 | 0.000000 | | 0.0000 | | 1.000000 | 60.931 |

Table 2 for FIG. 5
FACE 5

| | |
|---|---|
| K | 0.0000000000 |
| C1 | −7.9924337006e−08 |
| C2 | 2.7057877824e−12 |
| C3 | −1.6496548992e−16 |
| C4 | 2.0725249710e−21 |

Table 3 for FIG. 5
FACE 20

| | |
|---|---|
| K | 0.0000000000 |
| C1 | −2.0443114072e−08 |
| C2 | 2.0775994625e−13 |
| C3 | 8.8606230113e−18 |
| C4 | −1.0981504658e−21 |

Table 4 for FIG. 5
FACE 26

| | |
|---|---|
| K | 0.0000000000 |
| C1 | 9.1402583991e−08 |
| C2 | 6.2127922914e−13 |
| C3 | −1.8883297185e−16 |
| C4 | 4.4093426130e−20 |

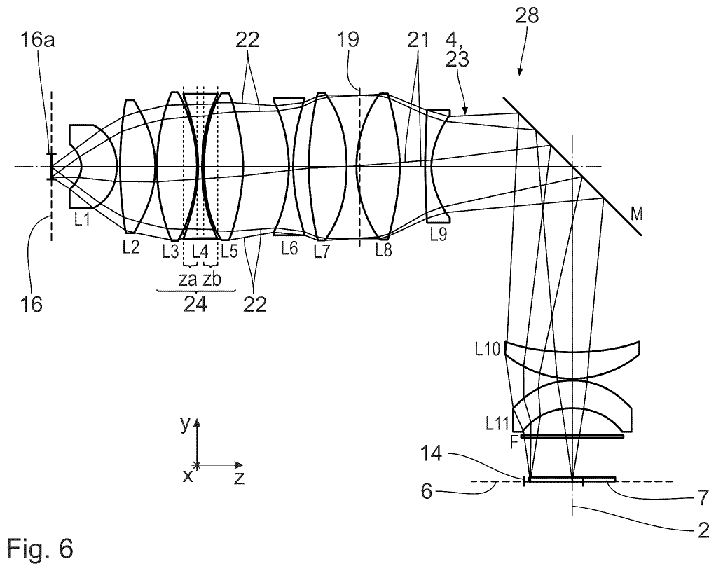

With reference to FIG. 6, a description is given below of a further embodiment of an illumination optical unit 28, which can be used instead of the illumination optical unit 20 as REMA lens in the projection exposure apparatus 1. Components and functions that correspond to those which were already explained above with reference to FIGS. 1 to 5 and for example with reference to FIGS. 2 and 5 have the same reference signs and are not discussed in detail again.

The illumination optical unit 28 has a total of eleven lens elements L1 to L11.

The lens elements L1 to L5 form a condenser lens-element group. The lens elements L7 to L9 form a lens-element group close to the pupil. The lens elements L10 and L11 form a field lens-element group. The lens elements L3 to L5 in turn form a lens-element triplet with two sectional plane coordinate regions za, zb in accordance with what was explained above in connection for example with FIG. 2.

The lens elements L1 to L3, L5, L7, L8, L10 and L11 are made of quartz glass (SILUV) with high UV transmission. The lens elements L4, L6 and L9 are made of flint glass (LLF1). The lens elements L1 to L11 of the illumination optical unit 28 are thus made of two different lens-element materials.

The illumination optical unit 28 has an overall transmission of 91.4%.

The pupil plane 19 is between the lenses L7 and L8, which form a quartz-glass doublet. In combination therewith, the following lens element L9 constitutes a constriction lens-element group in front of the deflection mirror M, which leads to a constriction of a diameter of an overall beam in the imaging beam path 22 compared to a maximum diameter of the overall beam in the imaging beam path 22 in front of the constriction of at least 25%. In the illumination optical unit 28, the maximum constriction of the overall beam is at the exit face of the lens element L9, where a constriction of approximately 27% takes place compared to the maximum diameter of the overall beam present in the region of the pupil plane 19. This constriction of the overall beam reduces size issues for the deflection mirror M.

The following tables show design data for the illumination optical unit 28 according to FIG. 6.

An exit face of the lens element L2, an exit face of the lens element L8 and an exit face of the lens element L10 are in the form of asphere faces, the coefficients of which are shown in Tables 2 to 4 for FIG. 6.

The deflection mirror M is between the lens elements L9 and L10.

Table 1 for FIG. 6

| | | | | | REFRACTIVE | |
|---|---|---|---|---|---|---|
| | | | | | INDEX | |
| FACE | RADII | | THICKNESS | GLASSES | 365.5 nm | SEMIDIAMETER |
| 1 | 0.000000 | | 0.0000 | | 1.000000 | 15.201 |
| 2 | 0.000000 | | 43.3000 | | 1.000000 | 15.201 |
| 3 | −43.439583 | | 50.6500 | SILUV | 1.474477 | 34.698 |
| 4 | −68.925441 | | 4.1800 | | 1.000000 | 61.674 |
| 5 | 570.575000 | | 50.4400 | SILUV | 1.474477 | 91.604 |
| 6 | −136.558125 | Asphere | 2.0500 | | 1.000000 | 95.483 |
| 7 | 293.599500 | | 59.0000 | SILUV | 1.474477 | 106.299 |
| 8 | −225.232600 | | 3.6200 | | 1.000000 | 106.392 |
| 9 | −267.466900 | | 5.7800 | LLF1 | 1.579164 | 103.860 |
| 10 | 250.184200 | | 6.2200 | | 1.000000 | 103.752 |
| 11 | 228.857800 | | 56.1500 | SILUV | 1.474477 | 106.663 |
| 12 | −291.355700 | | 63.9500 | | 1.000000 | 106.711 |
| 13 | −205.344500 | | 5.4700 | LLF1 | 1.579164 | 95.212 |
| 14 | 294.275900 | | 20.9400 | | 1.000000 | 98.806 |
| 15 | 433.867600 | | 54.2600 | SILUV | 1.474477 | 105.066 |
| 16 | −194.232400 | | 7.8000 | | 1.000000 | 106.506 |
| 17 | 0.000000 | Stop | 2.2200 | | 1.000000 | 103.237 |
| 18 | 179.716800 | | 63.3800 | SILUV | 1.474477 | 105.714 |
| 19 | −238.439675 | Asphere | 36.2200 | | 1.000000 | 103.396 |
| 20 | 1158.100000 | | 8.8600 | LLF1 | 1.579164 | 81.725 |
| 21 | 110.597400 | | 205.5100 | | 1.000000 | 72.804 |
| 22 | 0.000000 | Deflection | 264.5200 | | 1.000000 | 110.237 |
| | | mirror | | | | |
| 23 | −307.278600 | | 38.9300 | SILUV | 1.474477 | 94.832 |
| 24 | −132.613643 | Asphere | 0.7000 | | 1.000000 | 97.331 |
| 25 | 108.183907 | | 39.3800 | SILUV | 1.474477 | 85.514 |
| 26 | 89.225488 | | 42.4700 | | 1.000000 | 70.847 |
| 27 | 0.000000 | | 4.0000 | FK5 | 1.503934 | 69.760 |
| 28 | 0.000000 | | 55.7500 | | 1.000000 | 69.376 |
| 29 | 0.000000 | | 6.2500 | SUPRASIL | 1.474471 | 61.373 |
| 30 | 0.000000 | | 0.0000 | | 1.000000 | 60.932 |

Table 2 for FIG. 6
FACE 6

| | |
|---|---|
| K | 0.0000000000 |
| C1 | 6.4767751917e−08 |
| C2 | 3.8078941721e−12 |
| C3 | −3.9431936776e−17 |
| C4 | 1.1931539193e−20 |

Table 3 for FIG. 6
FACE 19

| | |
|---|---|
| K | 0.0000000000 |
| C1 | 8.1625981689e−08 |
| C2 | −2.2003555065e−12 |
| C3 | 1.0316433801e−16 |
| C4 | −2.6855291221e−21 |

Table 4 for FIG. 6
FACE 24

| | |
|---|---|
| K | 0.0000000000 |
| C1 | 5.4334222401e−08 |
| C2 | 1.4089970606e−12 |
| C3 | 1.1687952948e−17 |
| C4 | 7.1987388333e−21 |

An étendue of the illumination optical unit described above is 820 mm²sr. Depending on the embodiment of the illumination optical unit, the étendue may also have another value in the range between 700 mm²sr and 1200 mm²sr, for example. 750 mm²sr, 950 mm²sr or 1000 mm²sr.

A point image quality is at a spot diameter of less than 400 μm. To ascertain the point image quality, a generated point image is measured by way of an energy distribution of an imaging light sub-beam proceeding from the associated object point. A diameter of the point image is defined by the fact that 99.9% of the measured light power of the imaging light sub-bundle is within a point image circle with the diameter of the respective point image quality, that is in the present case within a circle with a diameter of less than 400 μm. A centre point of the respective circle is a point at which a respective main beam that proceeds from the assigned object point passes through the image plane 12 at the reference wavelength, in the present case at 365.5 nm.

Using the projection exposure apparatus 1, at least one part of the reticle 7 is imaged onto a region of a light-sensitive layer on the wafer 13 for the lithographic production of a micro-or nanostructured component. Depending on whether the projection exposure apparatus 1 is in the form of a scanner or a stepper, the reticle 7 and the wafer 13 are moved in a temporally synchronized manner in the y direction continuously in scanner operation or step by step in stepper operation.

What is claimed is:

1. A chromatically corrected imaging illumination optical unit configured to image an illumination conditioning field via an imaging beam path into an object field of a projection optical unit, the illumination optical unit comprising:
from seven to 12 lens elements in the imaging beam path,
wherein the illumination optical unit has an overall transmission for illumination light of at least 85%.

2. The illumination optical unit of claim 1, wherein, for at least three of the lens elements, the lens elements comprise aspherical lens elements.

3. The illumination optical unit of claim 1, wherein the illumination optical unit has an operating wavelength of 365 nm.

4. The illumination optical unit of claim 1, wherein the illumination optical unit is a dioptric illumination optical unit.

5. The illumination optical unit of claim 1, wherein the lens elements comprise at most three different lens-element materials.

6. The illumination optical unit of claim 1, wherein:
the from seven to 12 lens elements comprise a doublet of lens elements;
the doublet comprises a concave lens element fitted to a convex lens-element face of an adjacent lens element;
the doublet is configured so that, for at least one coordinate region of beam path coordinates along an optical axis of the illumination optical unit, a plane which is perpendicular to the optical axis in in this coordinate region intersects both the concave lens element of the doublet and the adjacent lens element of the doublet.

7. The illumination optical unit of claim 6, wherein, for at least three of the lens elements, the lens elements comprise aspherical lens elements.

8. The illumination optical unit of claim 1, wherein:
the from seven to 12 lens elements comprise a triplet of lens elements;
the triplet comprises a biconcave lens fitted between two convex lens-element faces;
the triplet is configured so that, for at least one coordinate region of beam path coordinates along an optical axis of the illumination optical unit, a plane which is perpendicular to the optical axis in in this coordinate region intersects both the biconcave lens element of the triplet and one of the convex lens elements of the triplet.

9. The illumination optical unit of claim 8, wherein:
two separate coordinate regions of beam path coordinates are separate from one another along the optical axis of the illumination optical unit;
for the two separate coordinate regions, a plane that is in the coordinate regions intersects both the biconcave lens element of the triplet and one of the convex lens elements of the triplet.

10. The illumination optical unit of claim 8, wherein, for at least three of the lens elements, the lens elements comprise aspherical lens elements.

11. The illumination optical unit of claim 1, further comprising a planar deflection mirror, wherein:
a diameter of an overall beam in the imaging beam path has a constriction;
the overall beam in the imaging beam path has a maximum diameter upstream of the constriction; and
the illumination optical unit is configured so that, upstream of the deflection mirror, the constriction is at least 25% of the maximum diameter.

12. The illumination optical unit of claim 1, wherein the illumination optical unit has a magnifying effect at least two between the illumination conditioning field and the object field.

13. The illumination optical unit of claim 1, wherein, for at least three of the lens elements, the lens elements comprise aspherical lens elements, and the illumination optical unit has an operating wavelength of 365 nm.

14. The illumination optical unit of claim 13, wherein the illumination optical unit is a dioptric illumination optical unit.

15. The illumination optical unit of claim 14, wherein the lens elements comprise at most three different lens-element materials.

16. The illumination optical unit of claim 13, wherein the lens elements comprise at most three different lens-element materials.

17. An optical system, comprising:
an illumination optical unit according to claim 1; and
a projection optical unit.

18. An illumination system, comprising:
an illumination optical unit according to claim 1;
a light source; and
an entry illumination optical unit configured to illuminate the illumination conditioning field.

19. A projection exposure apparatus, comprising:
a light source;
an illumination optical unit according to claim 1;
an entry illumination optical unit configured to illuminate the illumination conditioning field; and
a projection optical unit configured to image the object field into an image field.

20. A method of using a projection exposure apparatus comprising an illumination system and a projection optical unit, the method comprising:
using the illumination optical unit to illuminate an object field of the projection optical unit; and
using the projection optical unit to image the object field into an image field of the projection optical unit,
wherein the illumination system comprises an illumination optical unit according to claim 1.
